(19) United States
(12) Patent Application Publication
(10) Pub. No.: US 2016/0133869 A1
(43) Pub. Date: May 12, 2016

(54) DISPLAY DEVICE AND MANUFACTURING METHOD FOR THE SAME

(71) Applicant: JOLED INC., Tokyo (JP)

(72) Inventor: Kenichi NENDAI, Tokyo (JP)

(73) Assignee: JOLED INC., Tokyo (JP)

(21) Appl. No.: 14/935,508

(22) Filed: Nov. 9, 2015

(30) Foreign Application Priority Data
Nov. 10, 2014 (JP) 2014-228164

(51) Int. Cl. H01L 51/52; H01L 51/00; H01L 51/56

(52) U.S. Cl. CPC H01L 51/524; H01L 51/56; H01L 51/0005; H01L 51/5203

(57) ABSTRACT

A display device including: a substrate; first and second lower electrodes disposed with a gap therebetween; a partition wall containing resin material; first and second organic functional layers; and an upper electrode. The bottom face of the partition wall includes a first portion and two second portions. A height difference between the first portion and the second portion is no more than 30% of a height difference between the first portion and a maximum height point of a top face of the partition wall. The second portions each have a width no more than 20% of an overall width of the partition wall. The first portion corresponds to a part of the partition wall corresponding to the gap. The second portions respectively correspond to parts of the partition wall covering a portion of the first lower electrode and a portion of the second lower electrode.

This application is based on an application No. 2014-228164 filed in Japan, the contents of which are hereby incorporated by reference.

### BACKGROUND OF THE DISCLOSURE

(1) Technical Field

The present disclosure relates to a display device, such as an organic electroluminescence display panel, and to a manufacturing method for the same.

(2) Description of Related Art

A display device such as an organic electroluminescence display panel is typically configured from a substrate, a plurality of lower electrodes one for each sub-pixel, a plurality of light-emitting layers configured from an organic light-emitting material and each provided over a different one of the lower electrodes, and an upper electrode, layered in the stated order. Also, the display device is equipped with a hole injection layer, a hole transport layer, an electron injection layer, an electron transport layer, and a sealing layer, as required. In a situation where the display device is a top-emission device emitting light from the upper electrode side, the material of the lower electrodes is aluminum (Al) or a similar optically-reflective material, and the material of the upper electrode is indium tin oxide (hereinafter, ITO) or a similar optically-transparent material. Conversely, in a situation where the display device is a bottom-emission device emitting light from the substrate side, the material of the lower electrodes is optically transparent and the material of the upper electrode is optically reflective.

Incidentally, a manufacturing method for the light-emitting layers in the display device may be one of a vacuum vapor deposition method, where the organic light-emitting material is applied by vacuum vapor deposition, and a printing method, where an organic material ink is used in which the organic light-emitting material is dissolved in a solvent (see Japanese Patent Application Publication No. H11-87062). In a situation where organic light-emitting materials emitting different colors, namely red (hereinafter, R), green (hereinafter, G), and blue (hereinafter, B), are used, the vacuum vapor deposition method requires three masks each for providing apertures at positions corresponding to the sub-pixels in one color. The organic material of each color is blown in from above each mask. As a result, the organic light-emitting material is deposited over the lower electrodes and over each mask. Here, the organic light-emitting material deposited on the masks is wasted. On the other hand, the printing method enables the organic material ink to be applied only over the lower electrodes where targeted, and thus enables a reduction in wasted organic light-emitting material relative to the vacuum deposition method. In the printing method, a partition wall is typically formed in the gaps between neighboring lower electrodes in order to prevent the organic material ink from mixing among the colors R, G, and B. In addition, the partition wall has greater width than the gap between the neighboring lower electrodes. A portion of the partition wall is provided in the gap, and a remainder of the partition wall covers the lower electrodes. Disposing the remainder of the partition wall to cover the lower electrodes enables the partition wall to be formed in the gap between the lower electrodes despite any misalignment, during partition wall formation, caused by a margin of error for patterning applied to the lower electrodes.

In addition, the following process may be used, for example, as a process of manufacturing the partition wall on the substrate on which the lower electrodes have been formed. First, a partition wall material, in which a resin material having photosensitivity is combined with a solvent, is disposed so as to have one portion provided in the gap between the neighboring lower electrodes and a remainder covering the lower electrodes. Furthermore, the partition wall material is cured in order to evaporate the solvent in the resin material.

### SUMMARY OF THE DISCLOSURE

Incidentally, forming the partition wall using the above-described manufacturing method has been found to unintentionally result in the top face of the partition wall having a concave shape. Further, the current increase in display device definition has brought about a risk of ink applied to a region sandwiched between neighboring partition walls spilling and spreading as far as the top face of the partition wall. When the top face of the partition wall has a concave shape, inks for different light emission colors may spill and spread toward the center of the partition wall due to the top face of the partition wall growing lower toward the center. As a result, the inks may come into contact with one another on the top of the partition wall, which may result in ink color mixing.

In consideration of the above-described problem, the present disclosure aims to provide a display device having a partition wall whose top face has one of a flat shape and a convex shape, due to deformation of the partition wall that would provide the partition wall with a concave top face being prevented during manufacturing of the display device.

One aspect of the present disclosure is a display device including: a substrate; an electrode pair on the substrate, the electrode pair composed of a first lower electrode and a second lower electrode disposed with a gap therebetween in a direction along a top face of the substrate; a partition wall containing a resin material, the partition wall having greater width than the gap in the direction along the top face of the substrate, and including a first part and two second parts, the first part covering a portion of the top face of the substrate that corresponds to the gap, one of the two second parts covering a portion of the first lower electrode and the other of the two second parts covering a portion of the second lower electrode; a first organic functional layer and a second organic functional layer each including a light-emitting layer, the first organic functional layer disposed over a portion of the first lower electrode excluding the portion of the first lower electrode covered by the partition wall, the second organic functional layer disposed over a portion of the second lower electrode excluding the portion of the second lower electrode covered by the partition wall; and an upper electrode over the first organic functional layer and the second organic functional layer, wherein a bottom face of the partition wall includes a bottom face portion of the first part and respective bottom face portions of the second parts, a height of each of the bottom face portions of the second parts from the top face of the substrate is greater than a height of the bottom face portion of the first part from the top face of the substrate, a height of a top face of the partition wall from the top face of the substrate reaches a maximum at a maximum height point along the top face of the partition wall, a height difference between the bottom face portion of the first part and each of the bottom face portions of the second parts is no more than 30% of a height difference between the bottom face portion of the first part and the top face of the partition wall at the maximum height point; and the bottom face portions of the second parts each have a width no more than 20% of an overall width of the partition wall in the direction along the top face of the substrate.

### BRIEF DESCRIPTION OF THE DRAWINGS

These and other objects, advantages, and features of the technology pertaining to the present disclosure will become apparent from the following description thereof taken in conjunction with the accompanying drawings, which illustrate at least one specific embodiment of the technology pertaining to the present disclosure.

FIG. 1 is a cross-sectional diagram of an organic electroluminescence display panel as an example of a display device pertaining to an embodiment of the present disclosure.

FIG. 2 is a plan view diagram illustrating shapes and arrangement positions of partition walls and lower electrodes in the organic electroluminescence display panel illustrated in FIG. 1.

FIG. 3 is a schematic diagram illustrating dimensions of components of one of the partition walls in the organic electroluminescence display panel illustrated in FIG. 1.

FIGS. 4A, 4B, and 4C are diagrams illustrating a manufacturing method of the organic electroluminescence display panel illustrated in FIG. 1, where FIG. 4A illustrates a substrate preparation process, FIG. 4B illustrates formation processes for the lower electrodes and a hole injection layer, and FIG. 4C illustrates a resin material application process.

FIGS. 5A, 5B, and 5C are diagrams illustrating the manufacturing method of the organic electroluminescence display panel illustrated in FIG. 1, where FIG. 5A illustrates a process of arranging a mask over resin material, FIG. 5B illustrates a process of curing a partition wall material, and FIG. 5C illustrates a process of forming a hole transport layer.

FIGS. 6A, 6B, and 6C are diagrams illustrating the manufacturing method of the organic electroluminescence display panel illustrated in FIG. 1, where FIG. 6A illustrates an organic material ink application process, FIG. 6B illustrates an organic material ink drying process, and FIG. 6C illustrates formation processes of an electron injection layer, an upper electrode, and a sealing layer.

FIGS. 7A and 7B are schematic cross-sectional diagrams of the organic electroluminescence display panel, where FIG. 7A illustrates a situation immediately following application of the organic material ink, and FIG. 7B illustrates a situation after a certain period of time has elapsed since the application of the organic material ink.

FIGS. 8A and 8B are schematic cross-sectional diagrams prepared for discussing a change in the shape of a top face of a partition wall when a dimension of second portions of a bottom face of the partition wall (i.e., the c dimension) is changed while the entire width of the partition wall remains constant, where FIG. 8A illustrates a situation in which the dimension of the second portions of the bottom face of the partition wall (i.e., the c dimension) is large, and FIG. 8B illustrates a situation in which the dimension of the second portions of the bottom face of the partition wall (i.e., the c dimension) is small.

FIGS. 9A, 9B, and 9C are pictures of a partition wall cross-section taken using a scanning electron microscope (hereinafter, SEM), where a ratio of the width of the second portions of the bottom face of the partition wall to the entire width of the partition wall is 15% in FIG. 9A, 20% in FIG. 9B, and 30% in FIG. 9C.

FIGS. 10A, 10B, and 10C are charts indicating results of respective measurements of the partition wall in each of samples A, B, and C taken using an atomic force microscope (hereinafter, AFM), where the ratio of the width of the second portions of the bottom face of the partition wall to the entire width of the partition wall is 15% in FIG. 10A, 20% in FIG. 10B, and 30% in FIG. 10C.

FIGS. 11A, 11B, and 11C are charts indicating results of respective measurements of the partition wall in each of samples D, E, and F taken using the AFM, where the ratio of the width of the second portions of the bottom face of the partition wall to the entire width of the partition wall is 33% in FIG. 11A, 36% in FIG. 11B, and 40% in FIG. 11C.

FIGS. 12A and 12B are schematic cross-sectional diagrams prepared for discussing a change in the shape of the top face of the partition wall when a height difference between the first portion and the second portions of the bottom face of the partition wall is changed while the height difference between the first portion of the bottom face of the partition wall and a maximum height point of the top face of the partition wall remains constant, where FIG. 12A illustrates a situation in which the height difference between the first portion and the second portions of the bottom face of the partition wall is large, and FIG. 12B illustrates a situation in which the height difference between the first portion and the second portions of the bottom face of the partition wall is small.

FIG. 13 is a graph illustrating the relationship between a ratio of the height difference between the first portion and the second portions of the bottom face of the partition wall to the height difference between the first portion of the bottom face of the partition wall and the maximum height point of the top face of the partition wall, and a ratio of the width of the second portions of the bottom face of the partition wall to the entire width of the partition wall.

FIGS. 14A and 14B are schematic cross-sectional diagrams prepared for discussing the shape of the top face of the partition wall when the entire width of the partition wall is changed while the ratio of the width of the second portions of the bottom face of the partition wall to the entire width of the partition wall remains constant, where FIG. 4A illustrates a situation in which the entire width of the partition wall is large, and FIG. 14B illustrates a situation in which the entire width of the partition wall is small.

FIG. 15 is a schematic cross-sectional diagram illustrating a modification of the organic electroluminescence display panel.

FIG. 16 is a schematic cross-sectional diagram illustrating another modification of the organic electroluminescence display panel.

FIGS. 17A and 17B are diagrams each illustrating a part of a manufacturing method of the organic electroluminescence display panel illustrated in FIG. 16, where FIG. 17A illustrates a process of preparing a substrate with a metallic film formed thereon, and FIG. 17B illustrates formation processes for the lower electrodes and hole injection layers.

### DESCRIPTION OF EMBODIMENT

One aspect of the present disclosure is a display device including: a substrate; an electrode pair on the substrate, the electrode pair composed of a first lower electrode and a second lower electrode disposed with a gap therebetween in a direction along a top face of the substrate; a partition wall containing a resin material, the partition wall having greater width than the gap in the direction along the top face of the substrate, and including a first part and two second parts, the first part covering a portion of the top face of the substrate that corresponds to the gap, one of the two second parts covering a portion of the first lower electrode and the other of the two second parts covering a portion of the second lower electrode; a first organic functional layer and a second organic functional layer each including a light-emitting layer, the first organic functional layer disposed over a portion of the first lower electrode excluding the portion of the first lower electrode covered by the partition wall, the second organic functional layer disposed over a portion of the second lower electrode excluding the portion of the second lower electrode covered by the partition wall; and an upper electrode over the first organic functional layer and the second organic functional layer, wherein a bottom face of the partition wall includes a bottom face portion of the first part and respective bottom face portions of the second parts, a height of each of the bottom face portions of the second parts from the top face of the substrate is greater than a height of the bottom face portion of the first part from the top face of the substrate, a height of a top face of the partition wall from the top face of the substrate reaches a maximum at a maximum height point along the top face of the partition wall, a height difference between the bottom face portion of the first part and each of the bottom face portions of the second parts is no more than 30% of a height difference between the bottom face portion of the first part and the top face of the partition wall at the maximum height point; and the bottom face portions of the second parts each have a width no more than 20% of an overall width of the partition wall in the direction along the top face of the substrate.

In the display device pertaining to one aspect of the present disclosure, the overall width of the partition wall may be no more than 10 μm.

In the display device pertaining to one aspect of the present disclosure, the bottom face portions of the second parts may each have a width no more than 1.0 μm in the direction along the top face of the substrate.

In the display device pertaining to one aspect of the present disclosure, the height difference between the bottom face portion of the first part and each of the bottom face portions of the second parts may be no more than 0.4 μm, and the height difference between the bottom face portion of the first part and the top face of the partition wall at the maximum height point may be no less than 1.4 μm.

In the display device pertaining to one aspect of the present disclosure, the top face of the partition wall may include inclined portions and a central portion between the inclined portions, each of the inclined portions inclining upward towards the central portion from a corresponding one of two ends of the partition wall in the direction along the top face of the substrate, and each of the inclined portions may have a width equal to or greater than the width of each of the bottom face portions of the second parts in the direction along the top face of the substrate.

One aspect of the present disclosure is a manufacturing method for a display device, including: preparing a substrate; forming an electrode pair on the substrate, the electrode pair composed of a first lower electrode and a second lower electrode disposed with a gap therebetween in a direction along a top face of the substrate; disposing partition wall material containing resin material; forming a partition wall by curing the partition wall material, the partition wall having greater width than the gap in the direction along the top face of the substrate, and including a first part and two second parts, the first part covering a portion of the top face of the substrate that corresponds to the gap, one of the two second parts covering a portion of the first lower electrode and the other of the two second parts covering a portion of the second lower electrode; forming a first organic functional layer and a second organic functional layer by applying an ink over a portion of the first lower electrode excluding the portion of the first lower electrode covered by the partition wall and applying an ink over a portion of the second lower electrode excluding the portion of the second lower electrode covered by the partition wall, respectively, and drying the inks; and forming an upper electrode over the first organic functional layer and the second organic functional layer, wherein a bottom face of the partition wall includes a bottom face portion of the first part and respective bottom face portions of the second parts, a height of each of the bottom face portions of the second parts from the top face of the substrate is greater than a height of the bottom face portion of the first part from the top face of the substrate, a height of a top face of the partition wall from the top face of the substrate reaches a maximum at a maximum height point along the top face of the partition wall, a height difference between the bottom face portion of the first part and each of the bottom face portions of the second parts is no more than 30% of a height difference between the bottom face portion of the first part and the top face of the partition wall at the maximum height point; and the bottom face portions of the second parts each have a width no more than 20% of an overall width of the partition wall in the direction along the top face of the substrate.

In the display device pertaining to one aspect of the present disclosure, the bottom face portions of the second parts each have a width no more than 20% of an overall width of the partition wall. Experimentation has found that, when the partition wall is configured as such, the top face of the partition wall has a convex shape or a concave shape with a depth less than 50 nm, provided that the height difference between the bottom face portion of the first part and each of the bottom face portions of the second parts is no more than 30% of the height difference between the bottom face portion of the first part and the top face of the partition wall at the maximum height point.

Thus, a display device is provided that has a partition wall whose top face has one of a flat shape and a convex shape, due to deformation of the partition wall that would provide the partition wall with a concave top face being prevented during manufacturing of the display device.

An embodiment of the present disclosure is described in detail with reference to the drawings. An organic electroluminescence display panel is depicted as an example of the display device pertaining to one aspect of the present disclosure.

### Embodiment

### 1. Display Device Configuration

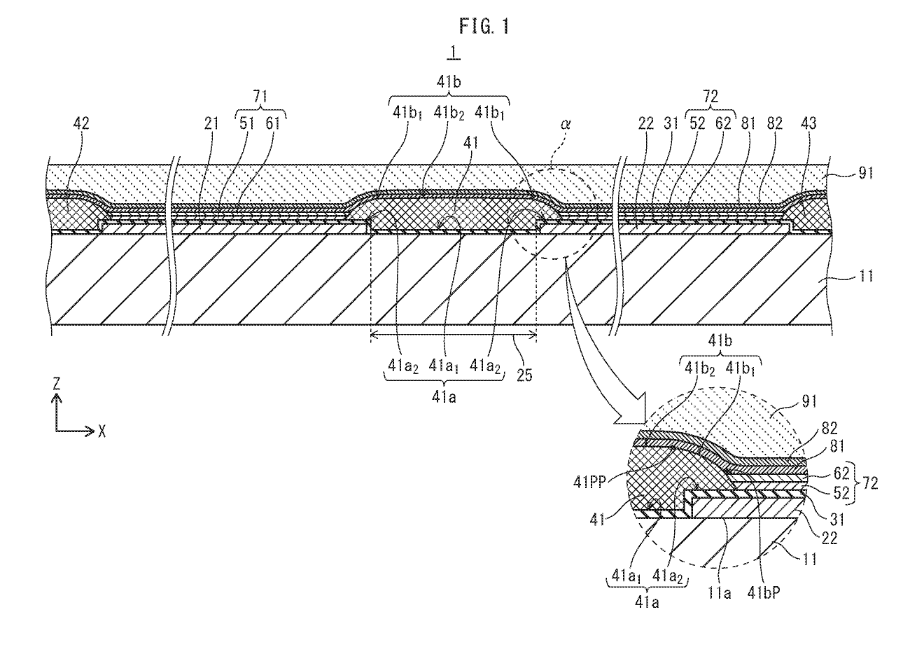

FIG. 1 is a schematic cross-sectional diagram of a display device 1, which is one example of the display device pertaining to the present disclosure. FIG. 1 illustrates a part of the display device 1 corresponding to two sub-pixels. The display device 1 includes a substrate 11, a first lower electrode 21 and a second lower electrode 22, a hole injection layer 31, a first partition wall 41, a second partition wall 42, and a third partition wall 43, a first organic functional layer 71 and a second organic functional layer 72, an electron injection layer 81, an upper electrode 82, and a sealing layer 91. In the present embodiment, the first organic functional layer 71 includes a hole transport layer 51 and a first light-emitting layer 61. The second organic functional layer 72 likewise includes a hole transport layer 52 and a second light-emitting layer 62. For example, the light emitted by the first light-emitting layer 61 may be green, and the light emitted by the second light-emitting layer 62 may be blue. In addition, the display device 1 is a top emission device emitting light from the top. The individual components are described in detail below.

### (1) Substrate

The substrate 11 is, for example, a thin film transistor (hereinafter, TFT) substrate over which an inter-layer insulation layer has been laminated. The TFT substrate includes, for example, a plastic substrate and TFTs and wiring that are formed on the plastic substrate. Disposing the inter-layer insulation over the TFT substrate serves to planarize a top face 11a of the substrate 11. The material for the inter-layer insulation is, for example, an organic resin such as one of a polyimide, polyamide, and acrylic resin.

### (2) Lower Electrodes

The first lower electrode 21 and the second lower electrode 22 each correspond to one sub-pixel. Specifically, the first lower electrode 21 and the second lower electrode 22 are arranged over the substrate 11 with a gap 25 therebetween. The first lower electrode 21 and the second lower electrode 22 each have a thickness of, for example, no more than 400 nm. Given that the display device 1 is a top emission panel emitting light from the top, the first lower electrode 21 and the second lower electrode 22 must reflect light. As such, the material for the first lower electrode 21 and the second lower electrode 22 is, for example, one of aluminum (Al), an alloy including aluminum, silver (Ag), and a silver alloy. Although not visible in this cross-sectional diagram, a third lower electrode is also present, in addition to the first lower electrode 21 and the second lower electrode 22. The third lower electrode is described later.

### (3) Hole Injection Layer

The hole injection layer 31 serves to improve the hole injection performance from the first lower electrode 21 to the first light-emitting layer 61 and from the second lower electrode 22 to the second light-emitting layer 62. In the present embodiment, no patterning is applied to the hole injection layer 31, which covers the first lower electrode 21, the second lower electrode 22, and a portion of the substrate 11 positioned in the gap 25. The thickness of the hole injection layer 31 is, for example, from 5 nm to 20 nm. The material for the hole injection layer 31 is, for example, one of tungsten oxide (WOₓ), molybdenum oxide (MoOₓ), and molybdenum tungsten oxide (MoWOₓ).

### (4) Partition Walls

The first partition wall 41 is provided over the hole injection layer 31. The width of the first partition wall 41 is greater than the width of the gap 25. A portion of the first lower electrode 41 covers a portion of the top face 11a of the substrate 11 corresponding to the gap 25. The remainder of the first partition wall 41 covers a portion of the first lower electrode 21 and a portion of the second lower electrode 22.

The first partition wall 41 includes a bottom face 41a and a top face 41b. The bottom face 41a of the first partition wall 41 includes a first portion 41a1 positioned at a portion corresponding to the gap 25 over the substrate 11, and second portions 41a2 respectively positioned over the first lower electrode 21 and the second lower electrode 22. As described above, the first lower electrode 21 and the second lower electrode 22 are arranged over the substrate 11 with the gap 25 therebetween. As such, a difference in level is produced between the portion of the top face 11a of the substrate 11 corresponding to the gap 25 and the top faces of the first lower electrode 21 and the second lower electrode 22. Here, the thickness of the hole injection layer 31 is less than the height of this difference in level, and is substantially uniform at all positions. As such, the hole injection layer 31 does not fill out the difference in level. As a result, the difference in level is produced in the bottom face 41a of the first partition wall 41 as a difference in level between the first portion 41a1 and the second portions 41a2. The height of the second portions 41a2 from the top face 11a of the substrate 11 is greater than the height of the first portion 41a1 from the top face 11a of the substrate 11 by an amount corresponding to the thickness of the first lower electrode 21 and the second lower electrode 22.

The top face 41b of the first partition wall 41 includes a pair of inclined portions 41b1 and a central portion 41b2 between the inclined portions 41b1. Each of the incline portions 41b1 inclines upward towards the central portion 41b2 from a corresponding one of two ends 41bp of the first partition wall 41 in a width direction. The central portion 41b2 may be planar (i.e., substantially parallel to the top face 11a of the substrate 11, which encompasses the central portion 41b2 having a slightly concave surface). The height of the top face 41b of the first partition wall 41 from the top face 11a of the substrate 11 increases as approaching the central portion 41b2 from the ends 41bp, reaching a maximum at peak points 41pp (where the incline with respect to the top face 11a of the substrate 11 is zero). The peak points 41pp are the borders between the inclined portions 41b1 and the central portion 41b2. The first partition wall 41, the second partition wall 42, and the third partition wall 43 (hereinafter collectively termed partition walls 40 when there is no need to distinguish among them) all have the same shape. The material for the partition walls 40 may be, for example, an acrylic resin, a polyimide resin a novolac-type phenol resin, and so on.

### (5) Hole Transport Layers

Hole transport layer 51 and hole transport layer 52 serve to transport holes injected from the first lower electrode 21 and the second lower electrode 22 to the first light-emitting layer 61 and the second light-emitting layer 62, respectively. The hole transport layer 51 and the hole transport layer 52 are respectively provided over the first lower electrode 21 and the second lower electrode 22, across from the hole injection layer 31. The hole transport layer 51 and the hole transport layer 52 each have a thickness of, for example, from 10 nm to 50 nm. The material for the hole transport layer 51 and the hole transport layer 52 may be, for example, one of polyfluorene or a derivative thereof, and polyarylamine or a derivative thereof.

### (6) Light-Emitting Layers

The first light-emitting layer 61 and the second light-emitting layer 62 serve to emit light generated when holes and electrons are injected and recombine in an excited state. The first light-emitting layer 61 is provided over the first lower electrode 21, over a region of the first lower electrode 21 not covered by the first partition wall 41 or the second partition wall 42. Likewise, the second light-emitting layer 62 is provided over a region of the second lower electrode 22 that is not covered by the first partition wall 41 or the third partition wall 43. Although not illustrated in the cross-sectional diagram, the third light-emitting layer 63 is also present in addition to the first light-emitting layer 61 and the second light-emitting layer 62. The material for the first light-emitting layer 61 and the second light-emitting layer 62 may be, for example, one of an oxinoid compound, a perylene compound, and a coumarin compound.

### (7) Electron Injection Layer

The electron injection layer 81 is provided in order to improve electron injection performance from the upper electrode 82 toward the first light-emitting layer 61 and the second light-emitting layer 62. The electron injection layer 81 covers the partition walls 40, the first light-emitting layer 61, the second light-emitting layer 62, and the third light-emitting layer 63. The thickness of the electron injection layer 81 is, for example, 10 nm. The material for the electron injection layer 81 may be, for example, sodium fluoride (NaF).

### (8) Upper Electrode

The upper electrode 82 is provided over the electron injection layer 81. The thickness of the upper electrode 82 is, for example, 100 nm. Given that the display device 1 is a top emission panel emitting light from the top, the upper electrode 82 is optically transmissive. As such, the material for the upper electrode 82 may be, for example, one of indium tin oxide (ITO) and indium zinc oxide (IZO).

### (9) Sealing Layer

The sealing layer 91 serves as a barrier layer protecting the light-emitting layers against water, oxygen and so on infiltrating from above. The sealing layer 91 is arranged over the upper electrode 82. The material for the sealing layer 91 may be, for example, silicon nitride (SiNₓ), silicon oxide (SiOₓ), or the like, and the sealing layer 91 may be manufactured by chemical vapor deposition (hereinafter, CVD).

### 2. Shape and Arrangement Positions of Lower Electrodes and Partition Walls

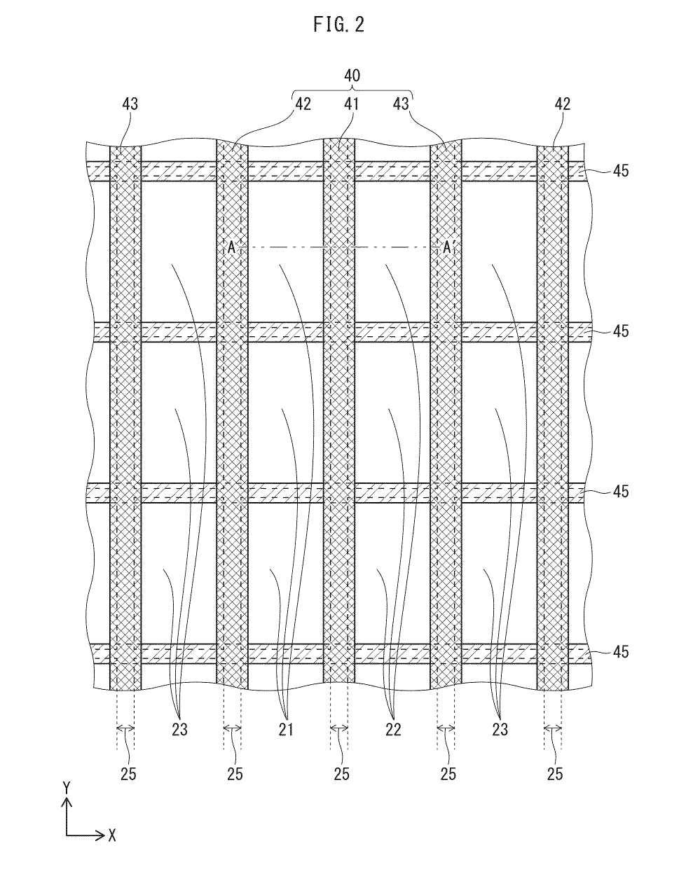

The shapes and arrangement positions of the lower electrodes and the partition walls are described next, with reference to the plan view diagram of FIG. 2. FIG. 1 is a cross-sectional diagram taken along line A-A′ of the plan view diagram of FIG. 2. The first lower electrode 21, the second lower electrode 22, and the third lower electrode 23 (hereinafter collectively termed lower electrodes 20 where there is no need to distinguish among them) are, for example, disposed in a matrix. The shape of each of the lower electrodes 20 is identical and may be, for example, rectangular. The lower electrodes 20 are separated by the gap 25. The lower electrodes 20 are disposed in parallel. The partition walls 40 are linear and aligned in parallel to a Y axis direction, being what is termed a line bank. Sub-partition walls 45 are formed to horizontally intersect the partition walls 40 in an X-axis direction. Each sub-partition wall 45 is formed linearly and is parallel to the X-axis direction. The sub-partition walls 45 are, for example, provided in order to prevent interruption of the upper electrode 82, extreme thinning of the upper electrode 82, etc., from occurring above level differences between the substrate 11 and the lower electrodes 20. Although not illustrated in the drawings, the first light-emitting layer 61, the second light-emitting layer 62, and the third light-emitting layer 63 are respectively disposed over the first lower electrode 21, the second lower electrode 22, and the third lower electrode 23. The light emitted by the third light-emitting layer 63 is red.

As it happens, the partition walls 40 extend uniformly and have constant width. The gap 25 between the lower electrodes 20 also extends uniformly with constant width. As such, the cross-sectional shape of the display device 1 is equal at all cross-sections taken parallel to the X-axis direction and passing through the first lower electrode 21 and the second lower electrode 22. That is, any cross-section taken parallel to the X-axis direction has the cross-sectional shape illustrated in the cross-sectional view of FIG. 1.

### 3. Shape and Dimensions of Partition Walls

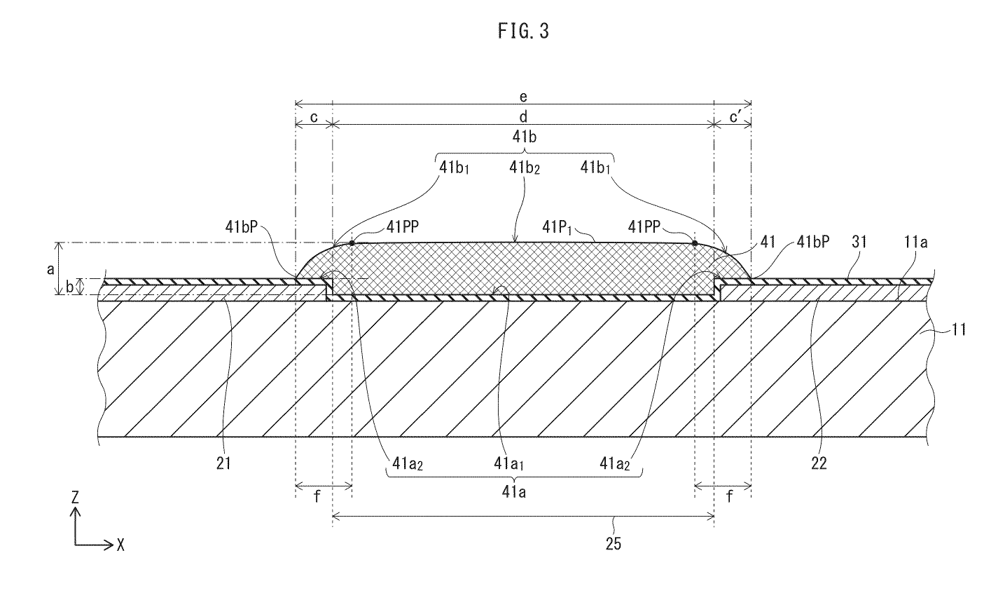

Furthermore, the shape and dimensions of the first partition wall 41 are explained in detail with reference to the schematic cross-sectional diagram of FIG. 3.

On the top face 41b of the first partition wall 41, a maximum height point 41pp where the height of the top face 41b of the first partition wall 41 from the top face 11a of the substrate 11 is at the maximum is present in plurality within the central portion 41b2, including the peak points 41pp described above. Reference symbol 41p1 in FIG. 3 illustrates one of such maximum height points other than the peak points 41pp. The thickness of the first partition wall 41, that is, a height difference a between the first portion 41a1 of the bottom face 41a of the first partition wall 41 and the maximum height point 41p1 of the first partition wall 41 is, for example, 1.4 μm. As described above, the first lower electrode 21 and the second lower electrode 22 each have a thickness of, for example, no more than 400 nm. Also, the thickness of the hole injection layer 31 is uniform, as described above. Specifically, no patterning is performed on the hole injection layer 31, which is provided not only over the first lower electrode 21 and the second lower electrode 22 but also on the portion of the substrate 11 corresponding to the gap 25. As such, a height difference b between the first portion 41a1 and the second portions 41a2 of the bottom face 41a of the first partition wall 41 is substantially equal to the thickness of the first lower electrode 21 and the second lower electrode 22. Accordingly, the height difference b between the first portion 41a1 and the second portions 41a2 of the bottom face 41a of the first partition wall 41 may be considered to be 30% of the height difference a between the first portion 41a1 of the bottom face 41a of the first partition wall 41 and the maximum height point 41p1 of the first partition wall 41. Of course, no such limitation is intended. Patterning may be performed on the hole injection layer 31, which may in this case be provided over the first lower electrode 21 and the second lower electrode 22 but not over the portion of the substrate 11 corresponding to the gap 25. In this case, the height difference between the first portion 41a1 and the second portions 41a2 of the bottom face 41a of the first partition wall 41 is substantially equal to the total of the thickness of the lower electrode (i.e., the first lower electrode 21 or the second lower electrode 22) and the thickness of the hole injection layer 31.

Also, respective widths c and c′ of the second portions 41a2 of the bottom face 41a of the first partition wall 41 are beneficially no less than 1.0 μm. A width e of the first partition wall 41 is beneficially no more than 10 μm. In addition, the width c of the second portions 41a2 of the bottom face 41a of the first partition wall 41 is beneficially no more than 20% of the width e of the first partition wall 41. The reason why providing dimensions in the above-listed numerical ranges is beneficial is described later. Further, width d indicates a width of the first portion 41a1 of the bottom face 41a of the first partition wall 41.

A width f of each of the inclined portions 41b1 of the top face 41b of the first partition wall 41, taken in parallel to the top face 11a of the substrate 11, is greater than the respective widths c and c′ of the second portions 41a2 of the bottom face 41a of the first partition wall 41. That is, each of the peak points 41pp of the top face 41b of the first partition wall 41 is located inwards in the X-axis direction relative to respective ends 21a and 21b of the first lower electrode 21 and the second lower electrode 22 facing the gap 25.

### 4. Organic Electroluminescence Display Panel Manufacturing Method

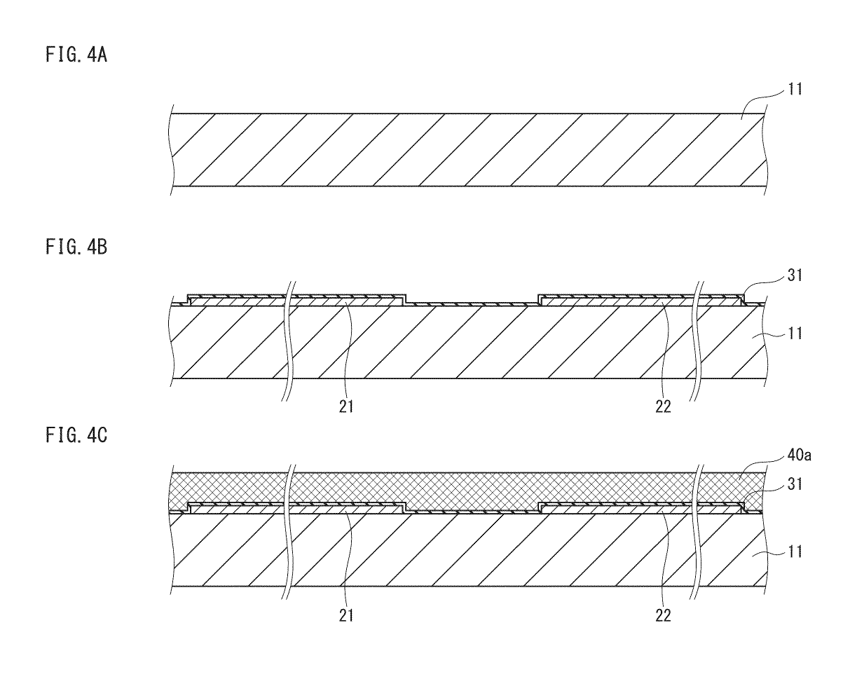

A manufacturing method for the display device 1 is described with reference to the cross-sectional diagrams of FIGS. 4A, 4B, and 4C to FIGS. 6A, 6B, and 6C. FIGS. 4A, 4B, and 4C to FIGS. 6A, 6B, and 6C are process method diagrams arranged chronologically.

As illustrated in FIG. 4A, the substrate 11 is prepared. Then, as illustrated in FIG. 4B, the first lower electrode 21, the second lower electrode 22, and the hole injection layer 31 are formed over the substrate 11. Specifically, first, the substrate 11 is loaded into a film formation container within a sputter film formation device. Next, a predetermined sputtering gas is introduced to the film formation container and a metal film is formed using reactive sputtering. Further, a photolithography method and an etching method are used to perform patterning on the metal film, thus forming the first lower electrode 21 and the second lower electrode 22. Furthermore, the reactive sputtering is used to form the hole injection layer 31 to cover the surfaces of the first lower electrode 21 and the second lower electrode 22 and the exposed surfaces of the substrate 11 entirely. Here, the metal film is formed with a thickness of, for example, from 20 nm to 50 nm. This is because later processes (e.g., the patterning process of the first partition wall 41, the second partition wall 42, and the third partition wall 43, and so on) reduce the thickness of the hole injection layer 31. Forming the metal film with a thickness of from 20 nm to 50 nm enables the hole injection layer 31 to have a thickness of from 5 nm to 20 nm upon completion of the manufacture of the display device 1.

As illustrated in FIG. 4C, a partition wall material film 40a is formed over the hole injection layer 31. Specifically, first, a partition wall material that includes a negative photosensitive resin material and a solvent is applied. Then, the partition wall material film 40a is formed upon heating at a temperature of from 80° C. to 110° C. for from two minutes to three minutes.

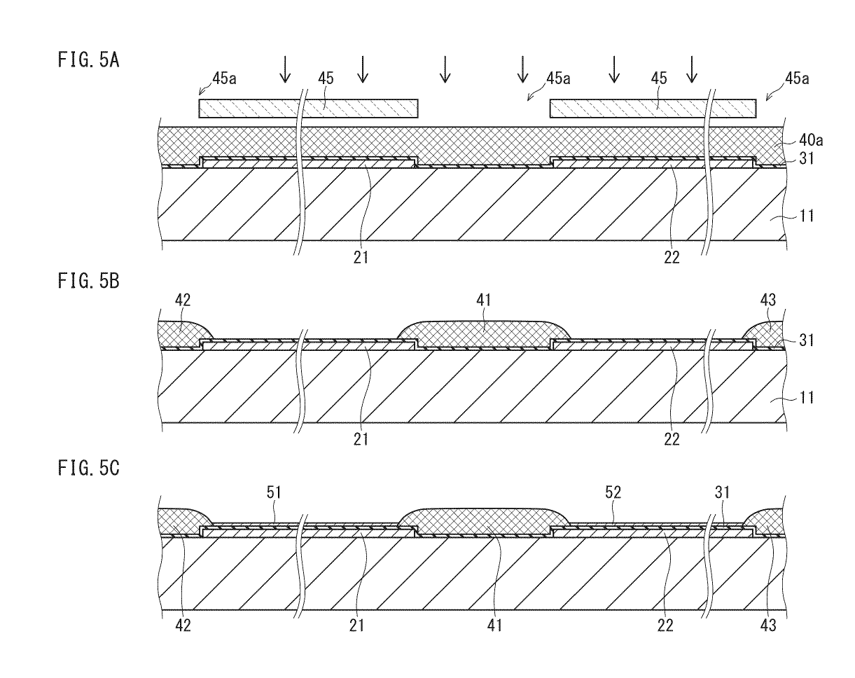

As illustrated in FIG. 5A, a mask 45, in which apertures 45a are provided, is arranged over the partition wall material film 40a. The mask 45 is then irradiated with light from above, as indicated by the black arrows of FIG. 5A. Specifically, a hard mask or the like may be used. The light used for irradiation may be, for example, ultraviolet rays. Irradiation with the ultraviolet rays causes hardening of the partition wall material film 40a, that is, enables exposure to be performed on the partition wall material film 40a.

Subsequently, the partition wall material film 40a, once hardened, is washed with a solvent to remove any non-hardened portions of the partition wall material film 40a, in other words, to develop the partition wall material film 40a. Furthermore, curing is performed at a temperature of from 200° C. to 230° C. for a duration of from 30 minutes to 120 minutes. Thus, as illustrated in FIG. 5B, the first partition wall 41, the second partition wall 42, and the third partition wall 43 are formed.

Next, as illustrated in FIG. 5C, the hole transport layer 51 and the hole transport layer 52 are respectively formed over the first lower electrode 21 and the second lower electrode 22. Specifically, a hole transport layer material is applied to a region between the first partition wall 41 and the second partition wall 42 and to a region between the first partition wall 41 and the third partition wall 43 using a printing method. The hole transport layer 51 and the hole transport layer 52 are formed upon subsequent drying. The hole transport layer 51 and the hole transport layer 52 each have a thickness of from 10 nm to 50 nm.

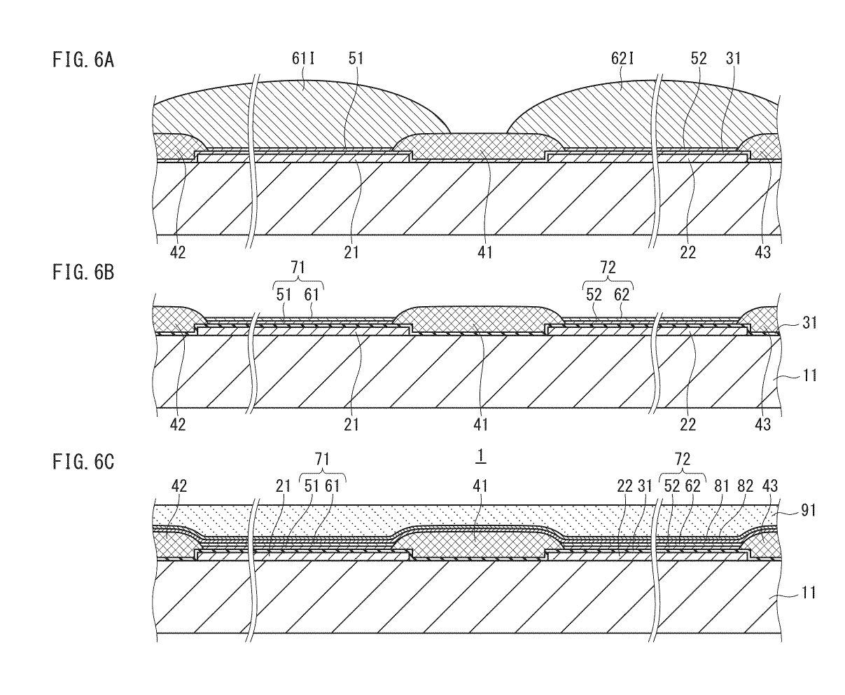

As illustrated in FIG. 6A, a first ink 611 and a second ink 621 are respectively applied to the region between the first partition wall 41 and the second partition wall 42 and to the region between the first partition wall 41 and the third partition wall 43, using the printing method. Although not visible in the cross-section, a third ink is also applied to a region between the second partition wall 42 and the third partition wall 43. The first ink 611, the second ink 621, and the third ink are each an ink combining a solvent and an organic light-emitting material of a different one of the colors of green, blue, and red.

The first light-emitting layer 61 and the second light-emitting layer 62 are formed by drying the first ink 611 and the second ink 621, as illustrated in FIG. 6B.

As illustrated in FIG. 6C, the electron injection layer 81, the upper electrode 82, and the sealing layer 91 are formed in the stated order so as to entirely cover the top faces of the first light-emitting layer 61, the second light-emitting layer 62, and the partition walls 40. Specifically, the electron injection layer 81, the upper electrode 82, and the sealing layer 91 are formed in the stated order using a sputtering method.

The display device 1 may be formed according to the above process.

### 5. Discussion

In the display device 1 described above, the top face of the partition wall has a flat shape and includes a central portion. Meanwhile, conventionally, there are cases where the top face of the partition wall of a display device has a concave shape, depending upon configuration of the display device. This is problematic in that inks containing organic light-emitting materials of different colors may combine during the process of forming the light-emitting layers with a printing method.

### (1) Problem of Concave Shape for Top Face of Partition Wall

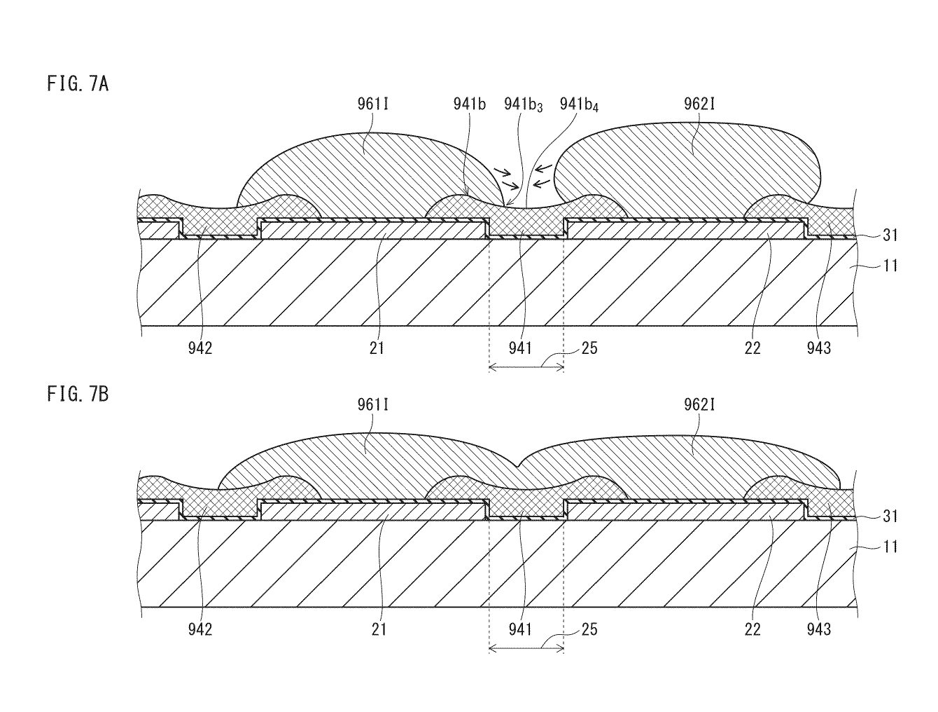

First, the mechanism causing ink mixing when the top face of the partition wall has a concave shape is explained with reference to FIGS. 7A and 7B. As illustrated by the comparative example of FIG. 7A, when a top face 941b of a first partition wall 941 has a concave shape, the top face 941b includes a curved portion 941b3. Further, the current increase in display device definition has brought about a risk of a first ink 961I and a second ink 962I spilling and spreading as far as the top face 941b of the first partition wall 941. When this occurs, the first ink 961I spreads along the curved portion 941b3 of the top face 941b toward a center 961b4 of the top face 941b. Similarly, the second ink 962I also spreads along the curved portion 941b3 of the top face 941b toward the center 961b4 of the top face 941b. As a result, and as illustrated in FIG. 7B, the first ink 961I and the second ink 962I come into contact with one another and ink color mixing occurs.

In view of this, this mixing of ink color can be constrained by forming the top face 41b of the first partition wall 41 with a flat shape, as in the display device 1.

(2) Shape of Partition Wall Top Face with Respect to Ratio c/e of c and e Dimensions

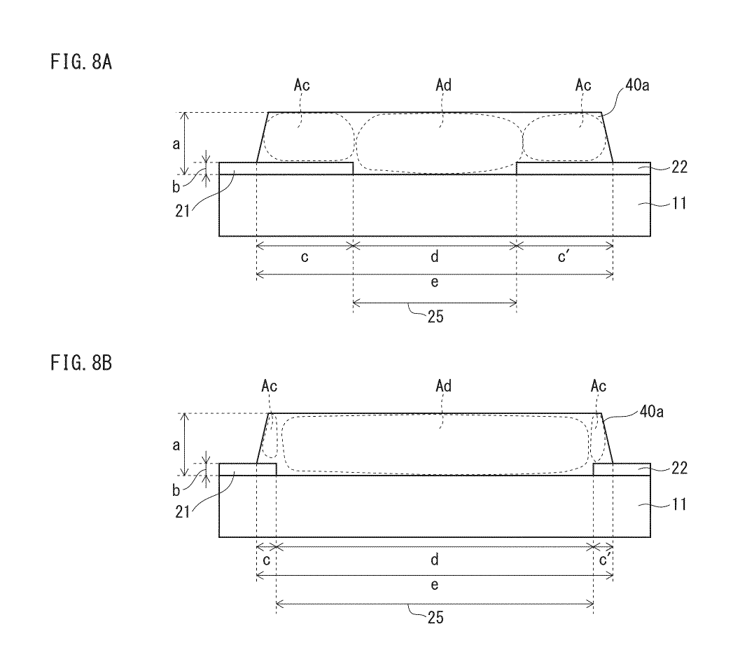

However, as result of inquiry, the inventors discovered that despite designing the top face of the partition wall to have a flat shape, the manufacturing process for the partition wall may unintentionally create a concave shape for the top face of the partition wall. As a result of dedicated investigation into the causes of this occurrence, the inventors found that the top face of the partition wall becomes concave due to contraction of the partition wall material during curing of the partition wall material after exposure. As a result of further inquiry, the inventors found that the shape of the top face of the partition wall changes in proportion to the ratio of the width of the second portions of the bottom face of the partition wall to the entire width of the partition wall. This theory is explained in detail below, with reference to FIGS. 8A and 8B. Note that in the following, an assumption is made that the partition wall material before curing and the partition wall after baking are invariant in terms of the respective widths c and c′ of the second portions of the bottom face of the partition wall and the entire width e of the partition wall. Further, an assumption is made that the respective widths c and c′ of the second portions of the bottom face of the partition wall are equal, and thus, in the following, the same width of both second portions of the bottom face of the partition wall is indicated by using “c”. For simplicity, the hole injection layer is not illustrated in FIGS. 8A and 8B.

FIGS. 8A and 8B are schematic cross-sectional diagrams illustrating the partition wall material film 40a prior to curing. FIG. 8A illustrates an example in which the ratio c/e of the width c of the second portions of the bottom face of the partition wall material film to the entire width e of the partition wall material film is large. FIG. 8B illustrates an example in which the ratio c/e of the width c of the second portions of the bottom face of the partition wall material film to the entire width e of the partition wall material film is small. The partition wall material film 40a disposed over the substrate 11 includes portion Ad having a width d, and portions Ac having a width c. Also, the curing of the partition wall material film 40a is performed over time in order to completely remove the solvent in the partition wall material film 40a. As such, assuming a uniform distribution of photosensitive resin material in the partition wall material film 40a, the contraction ratio of the partition wall material film 40a during curing is plausibly uniform at all points. Also, the thickness of portion Ac of the partition wall material film 40a is less than the thickness of portion Ad. The respective amount of contraction experienced by portion Ac and portion Ad is obtained by multiplying the thickness of portion Ac before curing and the thickness of portion Ad before curing by the contraction ratio. As such, the amount of contraction experienced by portion Ac of the partition wall material film 40a is less than the amount of contraction experienced by portion Ad.

As illustrated in FIG. 8A, when the ratio c/e of the width c of the second portions of the bottom face of the partition wall material to the entire width e of the partition wall material is large, there is a remarkable difference in partition wall thickness between portion Ac of the partition wall material film 40a and portion Ad of the partition wall material film 40a. Here, an example is considered where the width c of the second portions of the bottom face of the partition wall material film 40a is 30% of the entire width e of the partition wall material film 40a. In such a situation, the width of each portion Ac of the partition wall material film 40a is 30% of the entire width e and the width of portion Ad of the partition wall material film 40a is 40% of the entire width e. Here, upon curing the partition wall material film 40a, both end portions Ac experience a small amount of contraction at 30% and the center portion Ad experiences a large amount of contraction at 40%, resulting in a concave shape for the top face of the first partition wall.

Conversely, as illustrated in FIG. 8B, when the ratio c/e of the width c of the second portions of the bottom face of the partition wall material to the entire width e of the partition wall material is small, there is no appreciable difference in thickness of the partition wall between portion Ac of the partition wall material film 40a and portion Ad of the partition wall material film 40a. Here, an example is considered where the width c of the second portions of the bottom face of the partition wall material film 40a is 10% of the entire width e of the partition wall material film 40a. In such a situation, the width of each portion Ac of the partition wall material film 40a is 10% of the entire width e and the width of portion Ad of the partition wall material film 40a is 80% of the entire width e. Here, upon curing the partition wall material film 40a, both end portions Ac experience a small amount of contraction at 10% and the center portion Ad experiences a large amount of contraction at 80%. Due to the center portion Ad, having undergone a large amount of contraction, occupies most (80%) of the partition wall, the difference in amount of contraction between portion Ac and portion Ad becomes unremarkable. As such, the top face of the first partition wall has a planar portion.

This mechanism also suggests that, the larger the value of ratio c/e of the width c of the second portions of the bottom face of the partition wall to the entire width e of the partition wall is, the more concave the top face of the partition wall becomes.

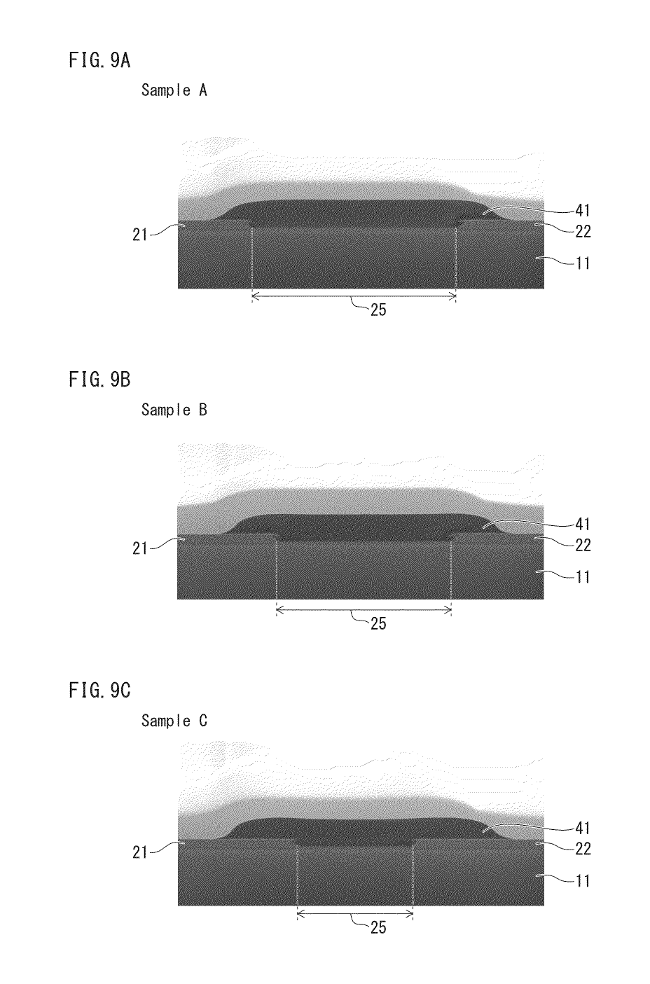

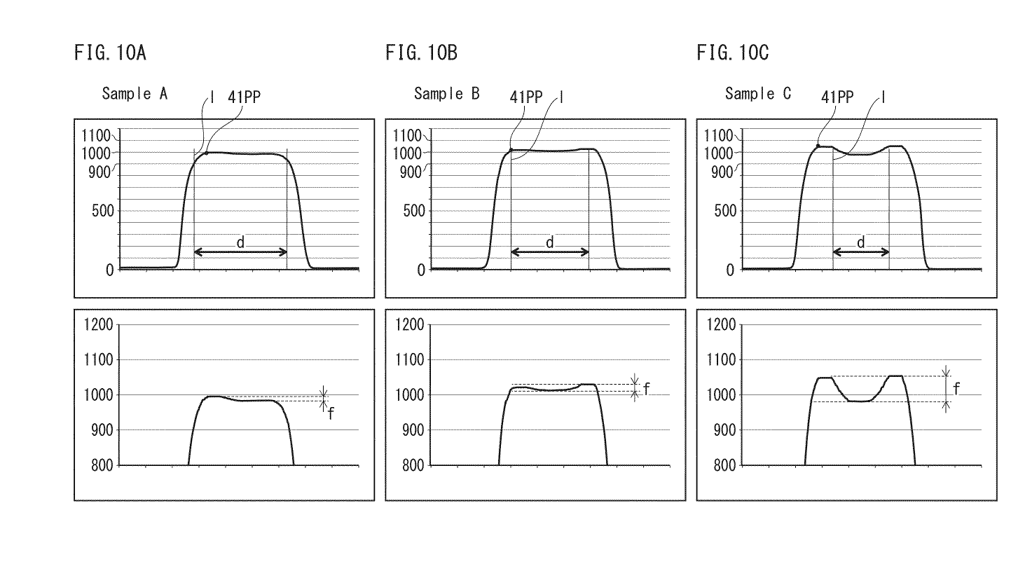

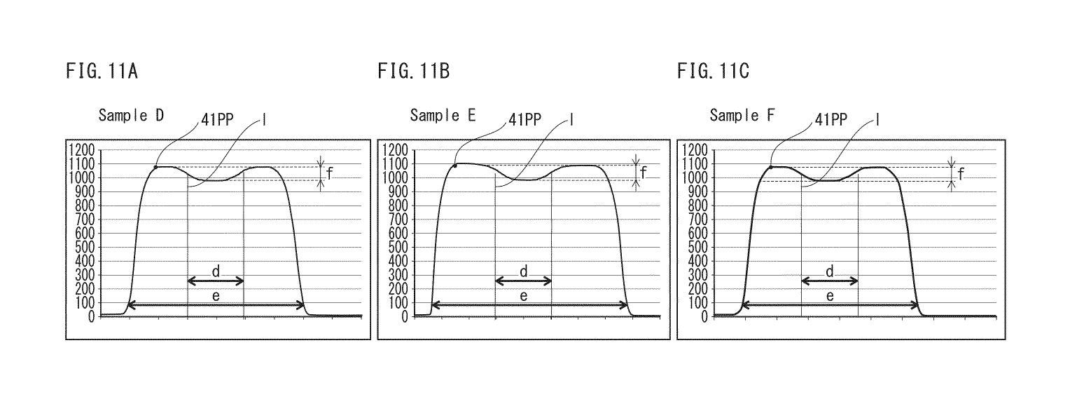

In consideration of the above-described theory, samples varying in thickness of the second portions of the bottom face of the partition wall were created and the formation of the partition wall was observed. FIGS. 9A, 9B, and 9C are pictures of cross-sections of the partition wall, taken with a scanning electron microscope (hereinafter, SEM). FIGS. 9A, 9B, and 9C respectively correspond to sample A, sample B, and sample C. FIGS. 10A, 10B, and 10C show results of measurements taken of the respective partition walls in the samples A, B, and C using an atomic force microscope (hereinafter, AFM). The bottom halves of FIGS. 10A, 10B and 10C correspond to expanded views of the respective top halves. FIGS. 11A, 11B, and 11C show results of measurements taken of the respective partition walls of samples D, E, and F using an AFM. In each of the samples A to F, the height difference b between the first portion and the second portions of the bottom face of the first partition wall was 350 nm. Also, the height difference between the top face of the substrate and the maximum height points of the top face of the first partition wall was set so as to be 1.35 μm. Regarding the first partition wall when actually completed, the height difference between the top face of the lower electrodes and the maximum height points on the top face of the first partition wall was from 1.0 μm to 1.1 μm in each of the samples A to F. As such, the height difference a between the first portion of the bottom face of the first partition wall and the maximum height points of the top face of the first partition wall was from 1.35 μm to 1.45 μm, with the height difference a differing between the samples by approximately 7%. Thus, it can be said that in each of the samples A to F, the ratio of the height difference b between the first portion and the second portions of the bottom face of the first partition wall to the height difference a between the first portion of the bottom face of the first partition wall and the maximum height points of the top face of the first partition wall was 30%. Furthermore, in each of the samples A to F, the width c of the second portion of the bottom face of the partition wall at the first lower electrode side and the width c of the second portion of the bottom face of the partition wall at the second lower electrode side were equal. Further, the width e of the first partition wall was 10 μm in samples A, B, C, and F, was 12 μm in sample D, and was 14 μm in sample E.

In sample A, the width c of the second portions 41a2 of the bottom face 41a of the first partition wall 41 was 1.5 μm. That is, the ratio c/e of the width c of the second portions 41a2 of the bottom face 41a of the first partition wall 41 to the entire width e of the first partition wall 41 was 15%. In this situation, as indicated in the lower half of FIG. 10A, a concavity f found in the top face 41b of the first partition wall 41 had a depth of 10 nm. Further, the peak points 41pp were positioned inwards than lines l extending from the respective ends of the lower electrodes that face the gap.

In sample B, the width c of the second portions 41a2 of the bottom face 41a of the first partition wall 41 was 2.0 μm. That is, the ratio c/e of the width c of the second portions 41a2 of the bottom face 41a of the first partition wall 41 to the entire width e of the first partition wall 41 was 20%. In this situation, as indicated in the lower half of FIG. 10B, the concavity f found in the top face 41b of the first partition wall 41 had a depth of 20 nm. Further, the peak points 41pp were positioned above lines l extending from the respective ends of the lower electrodes that face the gap.

In sample C, the width c of the second portions 41a2 of the bottom face 41a of the first partition wall 41 was 3.0 μm. That is, the ratio c/e of the width c of the second portions 41a2 of the bottom face 41a of the first partition wall 41 to the entire width e of the first partition wall 41 was 30%. In this situation, as indicated in the lower half of FIG. 10C, the concavity f found in the top face 41b of the first partition wall 41 had a depth of 50 nm. Further, the peak points 41pp were positioned outwards than lines l extending from the respective ends of the lower electrodes that face the gap.

As indicated in FIG. 11A, in sample D, width e of the first partition wall 41 was 12 μm, and width c of the second portions 41a2 of the bottom face 41a of the first partition wall 41 was 4.0 μm. That is, the ratio c/e of the width c of the second portions 41a2 of the bottom face 41a of the first partition wall 41 to the entire width e of the first partition wall 41 was 33%. In this situation, the concavity f found in the top face of the first partition wall 41 had a depth of 100 nm. Further, the peak points 41pp were positioned outwards than line l extending from the respective ends of the lower electrodes that face the gap.

As indicated in FIG. 11B, in sample E, the entire width e of the first partition wall 41 was 14 μm, and the width c of the second portions 41a2 of the bottom face 41a of the first partition wall 41 was 5.0 μm. That is, the ratio c/e of the width c of the second portions 41a2 of the bottom face 41a of the first partition wall 41 to the entire width e of the first partition wall 41 was 36%. In this situation, the concavity f found in the top face of the first partition wall 41 had a depth of 100 nm. Further, the peak points 41pp were positioned outwards than line l extending from the respective ends of the lower electrodes that face the gap.

As indicated in FIG. 11C, in sample F, the width c of the second portions 41a2 of the bottom face 41a of the first partition wall 41 was 4.0 μm. That is, the ratio c/e of the width c of the second portions 41a2 of the bottom face 41a of the first partition wall 41 to the entire width e of the first partition wall 41 was 40%. In this situation, the concavity f found in the top face of the first partition wall 41 had a depth of 100 nm. Further, the peak points 41pp were positioned outwards than line l extending from the respective ends of the lower electrodes that face the gap.

Samples A to F clearly demonstrate that increasing the width c of the second portions 41a2 of the bottom face 41a of the first partition wall 41 also increases the depth of the concavity f in the top face 41b of the first partition wall 41. In addition, when the ratio c/e of the width c of the second portions 41a2 of the bottom face 41a of the first partition wall 41 to the entire width e of the first partition wall 41 was one of 15% and 20%, the concavity f had a depth less than 50 nm, and the top face 41b of the first partition wall 41 was found to appear planar.

### (3) Ratio b/a of Dimensions b and a and Partition Wall Formation

As a result of further investigation, the inventors found that, in addition to changing relative to the ratio c/e of the width c of the second portions of the bottom face of the partition wall to the entire width e of the partition wall, the shape of the top face of the partition wall also plausibly changes in relation to a ratio b/a of the height difference b between the first portion and the second portions of the bottom face of the partition wall to the height difference a between the top face of the partition wall and the maximum height points. Here, the reason for using the height difference b between the first portion and the second portions of the bottom face of the first partition wall and not the thickness of the first lower electrode and the second lower electrode is that what is being considered is not only situations where the first partition wall is formed so as to directly cover the first lower electrode and the second lower electrode, but also situations where the hole injection layer is disposed between the first partition wall and each of the first lower electrode and the second lower electrode.

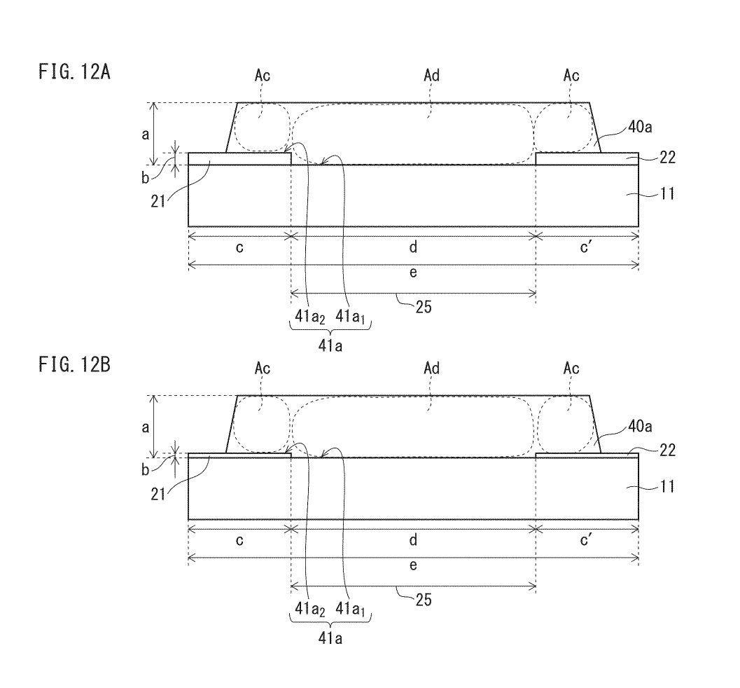

This theory is explained below, with reference to FIGS. 12A and 12B. FIGS. 12A and 12B are schematic cross-sectional diagrams illustrating the shape of partition wall material prior to curing. The only difference between FIG. 12A and FIG. 12B is the height difference b between the first portion 41a1 and the second portions 41a2 of the bottom face of the first partition wall 41.

As illustrated in FIG. 12A, a large height difference b between the first portion 41a1 and the second portions 41a2 of the bottom face of the first partition wall 41 results in a great difference between the respective amounts of contraction experienced by portion Ac and portion Ad of the partition wall material film 40a. Conversely, as illustrated in FIG. 12B, a small height difference b between the first portion 41a1 and the second portions 41a2 of the bottom face 41a of the first partition wall 41 results in a small difference between the respective amounts of contraction experienced by portion Ac and portion Ad of the partition wall material film 40a. As such, the smaller the ratio b/a of the height difference b between the first portion and the second portions of the bottom face of the partition wall to the height difference a between the first portion of the bottom face of the partition wall and the maximum height points on the top face of the partition wall, the less likely the top face of the first partition wall 41 is to be concave.

### (4) First Partition Wall Dimension Conditions

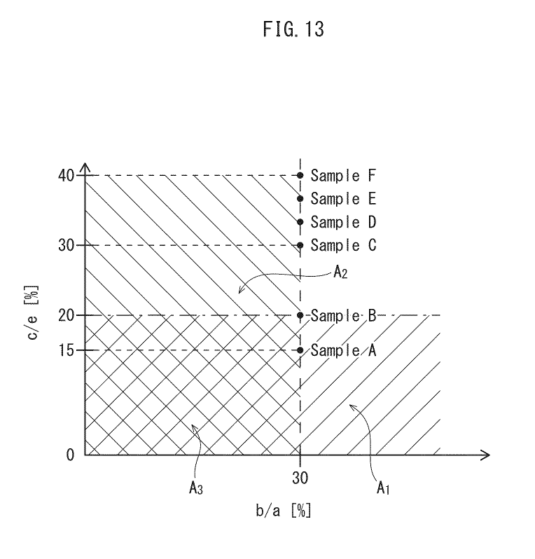

In consideration of the above, the inventors analyzed the conditions to be set regarding the dimensions of the first partition wall. FIG. 13 is a graph showing dimensional relationships for the first partition wall. The horizontal axis of the graph indicates the ratio b/a of the height difference b between the first portion 41a1 and the second portions 41a2 of the bottom face 41a of the first partition wall 41 to the height difference a between the first portion 41a1 of the bottom face 41a of the partition wall 41 and the maximum height points on the top face of the first partition wall 41. The vertical axis of the graph indicates the ratio c/e of the width c of the second portions 41a2 of the bottom face 41a of the first partition wall 41 to the entire width e of the first partition wall 41. The plotted points correspond to the samples A to F from FIGS. 10A to 10C and FIGS. 11A to 11C. As described above, the ratio b/a of the height difference b between the first portion 41a1 and the second portions 41a2 of the bottom face 41a of the first partition wall 41 to the height difference a between the first portion 41a1 of the bottom face 41a of the first partition wall 41 and the maximum height points on the top face of the first partition wall 41 was 30% in each of the samples A to F. Also, the ratio c/e of the width c of the second portions of the bottom face of the partition wall to the entire width e of the partition wall in each of the samples A to F was, in respective order, 15%, 20%, 30%, 33%, 36%, and 40%.

In samples A and B, the concavity in the top face of the first partition wall had a depth less than 50 nm, and the top face of the first partition wall may thus be considered to have a planar shape. Conversely, in samples C to F, the concavity in the top face of the first partition wall had a depth more than 50 nm, and the top face of the first partition wall therefore cannot be considered to have a planar shape. Further, as has been described with reference to FIGS. 8A and 8B, there is a tendency for the depth of the concavity in the top face of the first partition wall 41 to grow larger as the ratio of the width c of the second portions of the bottom face of the first partition wall 41 to the entire width e of the first partition wall 41 increases. In consideration of this tendency and of the ratio c/e being 20% in sample B, a first requirement among the dimension conditions for the first partition wall is that c/e is no more than 20%, which is the range indicated in region A1 of the graph of FIG. 13.

In addition, as described with reference to FIGS. 12A and 12B, there is a tendency for the top face of the first partition wall 41 to become less likely to be concave as the height difference b between the first portion 41a1 and the second portions 41a2 of the bottom face of the first partition wall 41 grows smaller. As such, in region A2 of the graph of FIG. 13, which is on the left-hand side of a straight line passing through samples A and B as plotted, there is a tendency for the top face of the first partition wall 41 to become less likely to be concave as the ratio a/b grows smaller, provided that the ratio c/e remains equal. In consideration of this tendency and of the ratio a/b being 30% in samples A and B, a second requirement among the dimension conditions for the first partition wall is that b/a is no more than 30%. Accordingly, the top face 41 of the first partition wall has a planar shape under conditions satisfying the requirements that the ratio c/e is no more than 20% and that the ratio b/a is no more than 30%, as indicated in region A3 in which both the first requirement and the second requirement hold.

As such, the width c of the second portions 41a2 of the bottom face 41a of the first partition wall 41 is no more than 20% of the entire width e of the first partition wall 41. Also, the height difference b between the first portion 41a1 and the second portions 41a2 of the bottom face 41a of the first partition wall 41 is no more than 30% of the height difference a between the first portion 41a1 of the bottom face 41a of the first partition wall 41 and the maximum height points 41p on the top face 41b of the first partition wall 41. As a result, the concavity in the top face 41b of the first partition wall 41 is within 50 nm and the top face 41b of the first partition wall 41 is considered to have a planar shape.

### (5) Shape of Partition Wall Top Face and e Dimension

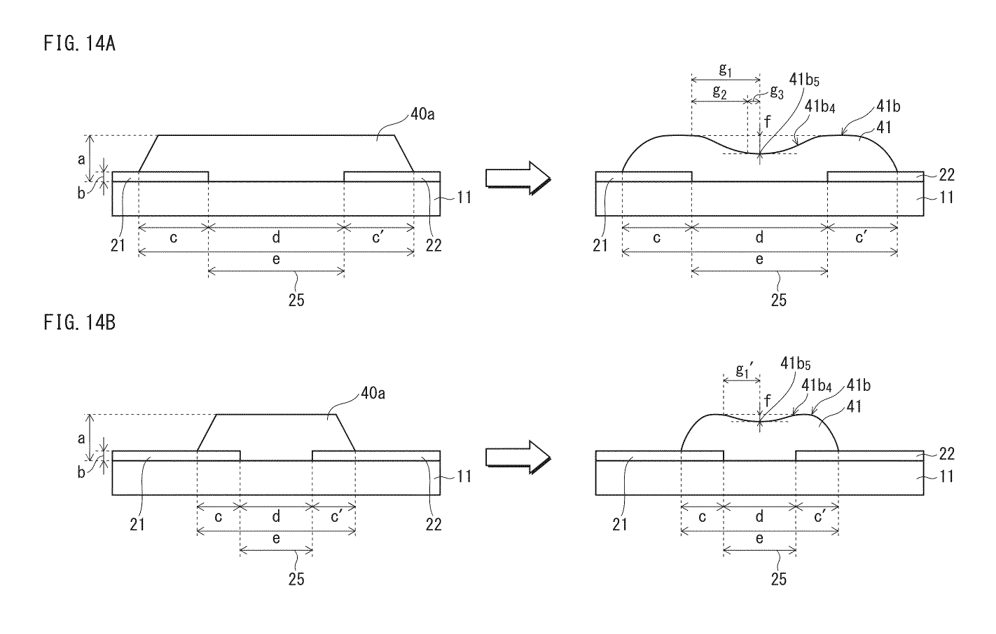

As a result of further investigation, the inventors found that the shape of the top face of the partition wall also changes in relation to the entire width e of the partition wall, despite the ratio c/e of the width c of the second portions of the bottom face of the partition wall to the entire width e of the partition wall being constant. This theory is explained below, with reference to FIGS. 14A and 14B. The left-hand portions of FIGS. 14A and 14B indicate the shape of the partition wall material prior to curing, and the right-hand portions of FIGS. 14A and 14B indicate the shape of the first partition wall after curing. Also, FIG. 14A illustrates an example in which the entire width e of the first partition wall is larger, and FIG. 14B illustrates in example in which the entire width e of the first partition wall is smaller. The ratio c/e of the width c of the second portions of the bottom face of the first partition wall to the entire width e of the first partition wall is equal between FIGS. 14A and 14B.

The width d of the first portion is greater in a situation where the ratio de is fixed and the entire width e of the partition wall material film 40a is larger (FIG. 14A), in comparison to a situation where the ratio c/e is fixed and the entire width e of the partition wall material film 40a is smaller (FIG. 14B). Accordingly, as illustrated in FIG. 14A, the top face 41b of the first partition wall 41 has a concave shape when the ratio c/e is fixed and the entire width e of the partition wall material film 40a is greater. Here, half-portion g1 of a concave portion 41b4 in the top face 41b of the first partition wall 41 is formed from a curved portion g2 and a central portion g3. Also, in FIG. 14B, where the entire width e of the partition wall material film 40a is smaller, the width d of the first portion is smaller in comparison to FIG. 14A. As such, the width of the concave portion 41b4 in the top face 41b of the first partition wall 41 is reduced and half-portion g1′ of the concave portion 41b4 is formed from the curved portion only. Here, the width of half-portion g1′ is smaller than the width of the curved portion g2. As a result, a central point 41b5 in the concave portion 41b4 of the top face 41b of the first partition wall 41 is higher in comparison to FIG. 14A. As a result, the concavity in the top face of the first partition wall 41 is not remarkable in FIG. 14B. Accordingly, it has been found that the smaller the entire width e of the first partition wall 41, the less remarkable the concavity in the top face 41b of the first partition wall 41, provided that the ratio c/e is fixed.

In samples A and B, which satisfy the first requirement and the second requirement described above, the entire width e of the first partition wall is 10 μm and the top face 41b of the first partition wall 41 has a planar shape. In consideration of the entire width e of the first partition wall in samples A and B, and of the theory that the concavity in the top face 41b of the first partition wall 41 becomes less remarkable as the entire width e of the first partition wall grows smaller, the concavity in the top face 41 is found to be even less remarkable when the entire width e of the first partition wall 41 is no more than 10 μm. As such, the entire width e of the first partition wall 41 is beneficially no more than 10 μm.

### [Modifications]

The above-described embodiment represents a beneficial example of the present disclosure. The numerical values, shapes, materials, components, arrangement positions and connection states of components, processes, ordering of processes, and so on given in the embodiment are intended as examples and not as limitations to the main subject of the present disclosure. Also, the present disclosure is not limited by the description of the above-described embodiment. Suitable modifications are applicable within a range that does not exceed the scope of the disclosure. Notably, the drawings discussed above are schematic drawings and are not necessarily precise depictions.

### 1. First Partition Wall Top Face Shape

In the above-described embodiment, the top face of the first partition wall has a planar shape. However, no such limitation is intended. The top face of the first partition wall may also have a convex shape. With such a shape, the top face of the first partition wall does not have a curved face in which the center of the first partition wall is at a low position. As such, contact between the respective inks applied over the first lower electrode and the second lower electrode on the top face of the first partition wall is constrained. As a result, color mixing of neighboring inks is constrained. A modification is described below, in which the top face of the first partition wall has a convex shape.

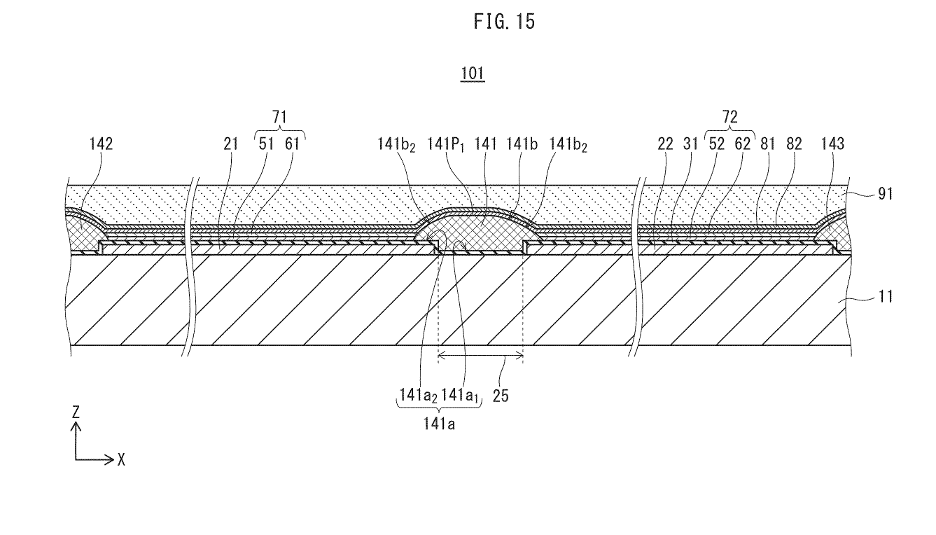

FIG. 15 is a schematic cross-sectional diagram of a display device 101 pertaining to this modification. A top face 141b of a first partition wall 141 does not include a planar portion, and is configured from a pair of inclined portions 141b2. As a result, the top face 141b of the first partition wall 141 has an overall shape that is convex. A maximum height point 141p1 of the first partition wall 141 is positioned at a substantially central portion of the top face 141b of the first partition wall 141.

In a hypothetical situation where the first partition wall 41 of the display device 1 discussed in the embodiment is of small width, the shape of the inclined portions is not expected to change. As such, gradually reducing the width of the first partition wall 41 causes the width of the central portion of the first partition wall 41 to diminish, until the central portion reaches zero width. Thus, in consideration of the shapes of the inclined portions obtained in samples A and B, the central portion plausibly reaches zero width when the entire width e of the first partition wall 141 is from 3 μm to 5 μm. Accordingly, in a situation where the height difference a between the first portion 141a1 of a bottom face 141a of the first partition wall 141 and the maximum height point 141p1 of the top face 141b of the first partition wall 141 is no more than 1.4 μm, the entire width e of the first partition wall 141 is realized within a range of from 3 μm to 5 μm. Thus, the top face of the first partition wall may be provided with a convex shape.

### 2. Anode and Hole Injection Layer

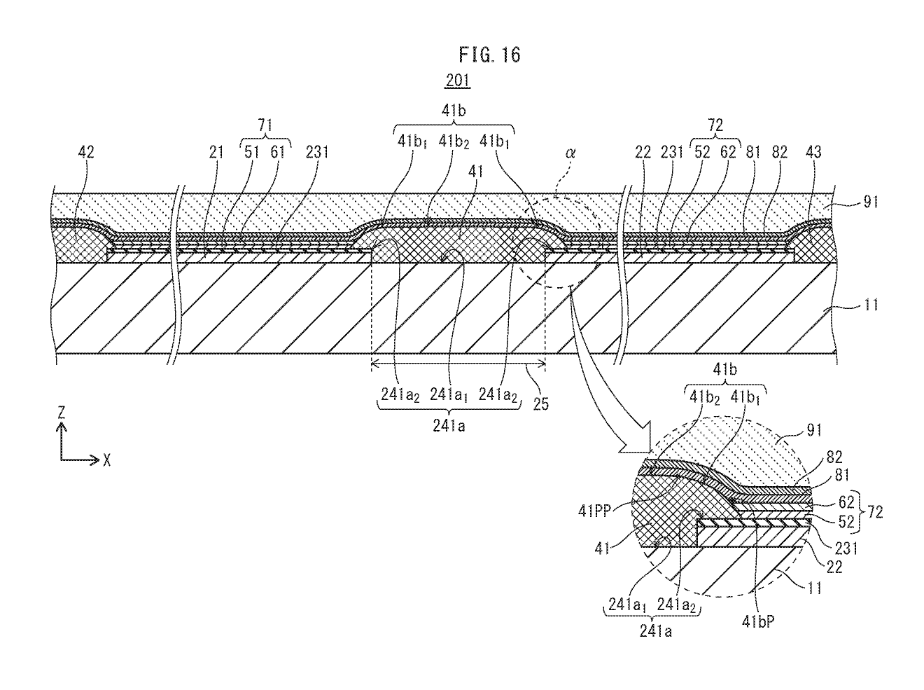

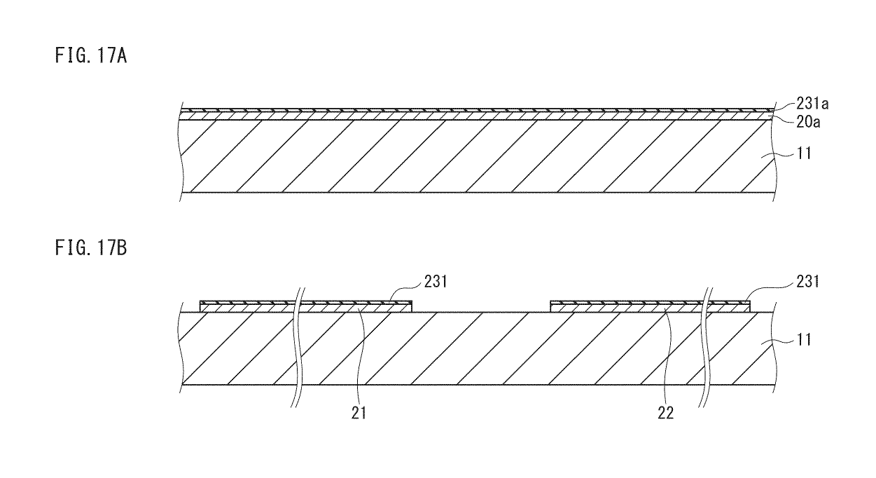

In the above-described embodiment, no patterning is applied to the hole injection layer, which covers the first lower electrode, the second lower electrode, and a portion of the substrate top face corresponding to the gap. However, no such limitation is intended. Patterning may be applied to the hole injection layer at the same time as the first lower electrode and the second lower electrode. This modification is described below with reference to FIGS. 16, 17A, and 17B.

FIG. 16 is a schematic cross-sectional diagram of a display device 201 pertaining to this modification. Hole injection layers 231 are formed so as to respectively cover the first lower electrode 21 and the second lower electrode 22. In this situation, similar to the embodiment, a bottom face 241a of the first partition wall 41 includes a first portion 241a1 positioned at a portion of the substrate 11 corresponding to the gap 25, and second portions 241a2 positioned over the first lower electrode 21 and the second lower electrode 22. The first portion 241a1 directly covers the substrate 11. As such, the height difference between the first portion 241a1 and the second portions 241a2 of the bottom face 241a of the first partition wall 41 is substantially equal to the total of the thickness of one lower electrode (i.e., the first lower electrode 21 of the second lower electrode 22) and the thickness of one of the hole injection layers 231.

The hole injection layers 231 may be formed using the manufacturing method illustrated in FIGS. 17A and 17B. First, as illustrated in FIG. 17A, a lower electrode material film 20a and a metallic film 231a are formed over the substrate 11. Furthermore, patterning is applied to the lower electrode material film 20a and the metallic film 231a using a photolithography method and an etching method. Thus, the first lower electrode 21, the second lower electrode 22, and the hole injection layers 231 may be formed as illustrated in FIG. 17B. A dry etching method is used, for example, when etching the metallic film 231a. Also, a wet etching method is used, for example, when etching the lower electrode material film 20a.

In addition, in the above-described embodiment and so on, the lower electrodes are formed from a single layer of aluminum (Al), an alloy that includes aluminum, silver (Ag), a silver alloy, and so on. However, no such limitation is intended. For example, each lower electrode may have a structure where a layer formed from an alloy that includes aluminum is sandwiched between two barrier layers formed from tungsten. In such a situation, a dry etching method is used when patterning the barrier layers.

### 3. Organic Functional Layer

In the above-described embodiment, a hole transport layer and a light-emitting layer are included in each of the organic functional layers. However, no such limitation is intended. Each organic functional layer may include only a light-emitting layer, or each organic functional layer may also include an electron block layer and a buffer layer in addition to a hole transport layer and a light-emitting layer.

In a configuration satisfying the first and second requirements described above, when the organic functional layers each include a hole transport layer and a light-emitting layer, and the hole transport layer is formed by a printing method using ink, then, for example, an ink applied over the first lower electrode and an ink applied over the second lower electrode may be constrained from coming into contact over the first partition wall. This is useful in a situation where, for example, the thickness of the hole transport layer is to be changed in accordance with the color R, G, or B of each sub-pixel. Here, forming at least one organic functional layer using a printing method enables the effects of the present disclosure to be obtained, even if the light-emitting layer is not formed using the printing method.

The technology pertaining to the present disclosure is useful as a display device, one example of which is an organic electroluminescence display panel.

Although the technology pertaining to the present disclosure has been fully described by way of examples with reference to the accompanying drawings, it is to be noted that various changes and modifications will be apparent to those skilled in the art. Therefore, unless such changes and modifications depart from the scope of the present disclosure, they should be construed as being included therein.

1. A display device, comprising:
a substrate;
an electrode pair on the substrate, the electrode pair composed of a first lower electrode and a second lower electrode disposed with a gap therebetween in a direction along a top face of the substrate;
a partition wall containing a resin material, the partition wall having greater width than the gap in the direction along the top face of the substrate, and including a first part and two second parts, the first part covering a portion of the top face of the substrate that corresponds to the gap, one of the two second parts covering a portion of the first lower electrode and the other of the two second parts covering a portion of the second lower electrode;
a first organic functional layer and a second organic functional layer each including a light-emitting layer, the first organic functional layer disposed over a portion of the first lower electrode excluding the portion of the first lower electrode covered by the partition wall, the second organic functional layer disposed over a portion of the second lower electrode excluding the portion of the second lower electrode covered by the partition wall; and
an upper electrode over the first organic functional layer and the second organic functional layer, wherein
a bottom face of the partition wall includes a bottom face portion of the first part and respective bottom face portions of the second parts,
a height of each of the bottom face portions of the second parts from the top face of the substrate is greater than a height of the bottom face portion of the first part from the top face of the substrate,
a height of a top face of the partition wall from the top face of the substrate reaches a maximum at a maximum height point along the top face of the partition wall,
a height difference between the bottom face portion of the first part and each of the bottom face portions of the second parts is no more than 30% of a height difference between the bottom face portion of the first part and the top face of the partition wall at the maximum height point; and
the bottom face portions of the second parts each have a width no more than 20% of an overall width of the partition wall in the direction along the top face of the substrate.

2. The display device according to claim 1, wherein
the overall width of the partition wall is no more than 10 μm.

3. The display device according to claim 2 wherein
the bottom face portions of the second parts each have a width no more than 1.0 μm in the direction along the top face of the substrate.

4. The display device according to claim 1, wherein
the height difference between the bottom face portion of the first part and each of the bottom face portions of the second parts is no more than 0.4 μm, and
the height difference between the bottom face portion of the first part and the top face of the partition wall at the maximum height point is no less than 1.4 μm.

5. The display device according to claim 1, wherein
the top face of the partition wall includes inclined portions and a central portion between the inclined portions, each of the inclined portions inclining upward towards the central portion from a corresponding one of two ends of the partition wall in the direction along the top face of the substrate, and
each of the inclined portions has a width equal to or greater than the width of each of the bottom face portions of the second parts in the direction along the top face of the substrate.

6. A manufacturing method for a display device, comprising:
preparing a substrate;
forming an electrode pair on the substrate, the electrode pair composed of a first lower electrode and a second lower electrode disposed with a gap therebetween in a direction along a top face of the substrate;
disposing partition wall material containing resin material; forming a partition wall by curing the partition wall material, the partition wall having greater width than the gap in the direction along the top face of the substrate, and including a first part and two second parts, the first part covering a portion of the top face of the substrate that corresponds to the gap, one of the two second parts covering a portion of the first lower electrode and the other of the two second parts covering a portion of the second lower electrode;
forming a first organic functional layer and a second organic functional layer by applying an ink over a portion of the first lower electrode excluding the portion of the first lower electrode covered by the partition wall and applying an ink over a portion of the second lower electrode excluding the portion of the second lower electrode covered by the partition wall, respectively, and drying the inks; and
forming an upper electrode over the first organic functional layer and the second organic functional layer, wherein
a bottom face of the partition wall includes a bottom face portion of the first part and respective bottom face portions of the second parts,
a height of each of the bottom face portions of the second parts from the top face of the substrate is greater than a height of the bottom face portion of the first part from the top face of the substrate,
a height of a top face of the partition wall from the top face of the substrate reaches a maximum at a maximum height point along the top face of the partition wall,
a height difference between the bottom face portion of the first part and each of the bottom face portions of the second parts is no more than 30% of a height difference between the bottom face portion of the first part and the top face of the partition wall at the maximum height point; and
the bottom face portions of the second parts each have a width no more than 20% of an overall width of the partition wall in the direction along the top face of the substrate.
